(19) United States
(12) Patent Application Publication
(10) Pub. No.: US 2026/0265577 A1
(43) Pub. Date: Sep. 10, 2026

(54) POLISHING COMPOSITION AND POLISHING METHOD USING THE SAME

(71) Applicant: FUJIMI INCORPORATED, Aichi (JP)

(72) Inventor: Ryo WAKABAYASHI, Aichi (JP)

(21) Appl. No.: 19/164,131

(22) PCT Filed: Mar. 22, 2024
(86) PCT No.: PCT/JP2024/011365

§ 371 Date: Sep. 10, 2025

(30) Foreign Application Priority Data
Mar. 30, 2023 (JP) 2023-055871

(51) Int. Cl. C09G 1/02; C09K 3/14

(52) U.S. Cl. CPC C09G 1/02; C09K 3/1409

(57) ABSTRACT

The present invention is to provide a means capable of improving redispersion properties of the sediment occurring in a polishing composition and reducing residual abrasive grains on a surface of an object to be polished (in particular, an object to be polished containing a resin and a filler) after polishing. The present disclosure relates to a polishing composition including abrasive grains, an anticaking agent, and a dispersing medium, wherein the abrasive grains are silica particles having an average particle size (D₅₀) of more than 1.0 μm and a circularity of primary particles of 0.90 or more, the anticaking agent includes inorganic particles different from the abrasive grains, and the product of the zeta potential of the abrasive grains and the zeta potential of the anticaking agent is positive.

### TECHNICAL FIELD

The present invention relates to a polishing composition and a method using the same.

### BACKGROUND ART

Conventionally, various studies of polishing compositions for various materials including resins have been made.

International Publication No. WO 2022/185793 (corresponding to Publication of U.S. Patent Application No. 2024/002697) discloses a polishing composition for an object to be polished containing a resin and a filler. More specifically, International Publication No. WO 2022/185793 (corresponding to Publication of U.S. Patent Application No. 2024/002697) discloses that residual abrasive grains on a surface of an object to be polished after polishing can be reduced with a polishing composition containing silica particles having an average particle size and a circularity equal to or more than specified values as abrasive grains, and a dispersing medium. Further, International Publication No. WO 2022/185793 (corresponding to Publication of U.S. Patent Application No. 2024/002697) discloses that although a polishing composition left to stand still causes sediment due to solid-liquid separation of the polishing composition, a polishing composition containing a redispersing agent allows the sediment to be redispersed into a liquid part.

### SUMMARY OF INVENTION

Through study of the stability of a polishing composition, the present inventor has found that with a long time left standing causes sediment to lose fluidity, resulting in a possibility of difficulty in redispersing the sediment. Accordingly, a polishing composition that achieves a high level of redispersion properties of the sediment has been required. Also, the present inventor has found that further improvement in reduction in the residual abrasive grains on a surface of an object to be polished (in particular, an object to be polished containing a resin and a filler) after polishing has been required. Therefore, the compatibility between the redispersion properties of the sediment occurring in a polishing composition and the reduction of residual abrasive grains on a surface of an object to be polished after polishing are required to be achieved.

Accordingly, the present invention has been made in view of the circumstances. An object of the present invention is to provide means capable of improving redispersion properties of the sediment occurring in a polishing composition and reducing residual abrasive grains on a surface of an object to be polished (in particular, an object to be polished containing a resin and a filler) after polishing.

### Solution to Problem

The present inventor has performed diligent study to solve the problem. As a result, the present inventor has found that the problem can be solved by a polishing composition including silica particles having a specific particle size and a specific circularity as abrasive grains, and inorganic particles as anticaking agent, with a positive product of the zeta potential of the abrasive grains and the zeta potential of the anticaking agent, and thereby the present invention has been completed.

Specifically, the problem to be solved of the present invention can be solved by the following means:

An embodiment of the present invention that can solve the problem relates to a polishing composition including abrasive grains, an anticaking agent, and a dispersing medium, wherein the abrasive grains are silica particles having an average particle size (D50) of more than 1.0 μm and a circularity of primary particles of 0.90 or more, the anticaking agent includes inorganic particles different from the abrasive grains, and the product of the zeta potential of the abrasive grains and the zeta potential of the anticaking agent is positive.

### DESCRIPTION OF EMBODIMENTS

Hereinafter, embodiments of the present invention will be described. The embodiments shown herein are examples of implementation of the technical idea of the present invention, which do not limit the present invention. Accordingly, all the other feasible embodiments, usage and operation technology conceivable by a person skilled in the art are included in the scope or gist of the present invention and in the invention described in the claims and the equivalents thereof. The embodiments described in the present description may be combined optionally to make another embodiment.

In the present description, unless otherwise specified, operations and measurement of physical properties are performed under conditions at room temperature (in the range of 20° C. or more and 25° C. or less)/a relative humidity of 40% RH or more and 50% RH or less.

### <Polishing Composition>

An embodiment of the present invention relates to a polishing composition including abrasive grains, an anticaking agent, and a dispersing medium, wherein the abrasive grains are silica particles having an average particle size (D50) of more than 1.0 μm and a circularity of primary particles of 0.90 or more, and the anticaking agent includes inorganic particles different from the abrasive grains, and the product of the zeta potential of the abrasive grains and the zeta potential of the anticaking agent is positive. According to the present embodiment, redispersion properties of the sediment occurring in a polishing composition are good, the fluidity of the sediment is preserved, and residual abrasive grains on a surface of an object to be polished (in particular, an object to be polished containing a resin and a filler) after polishing can be reduced. Since the polishing composition includes silica particles having the specific particle size and the specific circularity as abrasive grains and inorganic particles as the anticaking agent (excluding silica particles included as abrasive grains), and the product of the zeta potential of the abrasive grains and the zeta potential of the anticaking agent is positive (in other words, both the zeta potentials have the same signs), redispersion properties of the sediment occurring in the polishing composition are good and residual abrasive grains on a surface of an object to be polished (in particular, an object to be polished containing a resin and a filler) after polishing can be reduced. In other words, the good redispersion properties of the sediment occurring in a polishing composition and the reduction of residual abrasive grains on a surface of an object to be polished (in particular, an object to be polished containing a resin and a filler) after polishing can be achieved in a well-balanced manner. Also, the good redispersion properties of the sediment occurring in a polishing composition and the reduction of residual abrasive grains on a surface of an object to be polished (in particular, an object to be polished containing a resin and a filler) after polishing can be achieved in a well-balanced manner at a sufficient level. Therefore, according to the present embodiment, the redispersion properties of the sediment occurring in a polishing composition are good, and the reduction of residual abrasive grains on a surface of an object to be polished (in particular, an object to be polished containing a resin and a filler) after polishing can be achieved. In the following, the redispersion properties of the sediment occurring in the polishing composition are referred to also as “redispersion properties of the polishing composition”.

The polishing composition according to the present embodiment is supplied to an object to be polished typically in a form of a polishing liquid containing the polishing composition for use in polishing the object to be polished. The polishing composition according to the present embodiment may be, for example, diluted (typically with water) for use as polishing liquid, or directly used as polishing liquid. In other words, the concept of polishing composition in the technique related to the present embodiment includes both of a polishing composition which is supplied to an object to be polished for use in polishing the object to be polished (working slurry) and a concentrate which is diluted for use in polishing (concentrated liquid for working slurry). A concentration factor of the concentrate may be, for example, about 2 or more and 100 or less on volumetric basis, and an appropriate factor is usually about 5 or more and 50 or less on volumetric basis.

### [Abrasive Grains]

### <Silica Particles>

The abrasive grains contained in the polishing composition according to the present embodiment are silica particles having an average particle size (D50) of more than 1.0 μm and a circularity of primary particles of 0.90 or more. In the present description, unless otherwise specified, silica particles having an average particle size (D50) of more than 1.0 μm and a circularity of primary particles of 0.90 or more as abrasive grains are also referred to simply as “silica particles according to the present embodiment” or “silica particles”.

In an embodiment of the present embodiment, both of dry silica particles and wet silica particles are preferably used as the silica particles. Silica particles may be easily produced with appropriate reference to a known production method. Alternatively, as long as silica particles satisfy the average particle size (D50) and the circularity of primary particles as defined in the present embodiment, a commercially available product may be used. Examples of the production method of dry silica particles may include a flame hydrolysis method, a vaporized metal combustion method, and a melting method. Examples of the production method of wet silica particles (particularly colloidal silica particles) may include a sodium silicate method, an alkoxide method and a sol-gel method. Silica particles produced by any of the production methods are suitably used as the silica particles of the present invention as long as the average particle size (D50) and the circularity of primary particles as defined in the present embodiment are satisfied. Among these silica particles, dry silica particles are particularly preferred. As the production method thereof, a vaporized metal combustion method and a melting method are preferred.

In an embodiment, the silica particles as a raw material are silica particles obtained by a sodium silicate method. The sodium silicate method is typically a method in which activated silicic acid obtained through ion exchange from an alkali silicate aqueous solution such as water glass is used as raw material and subjected to grain growth.

In an embodiment, the silica particles as a raw material are silica particles obtained by an alkoxide method. The alkoxide method is typically a method in which alkoxysilane is used as raw material and subjected to hydrolytic condensation reaction.

In an embodiment, the silica particles as a raw material are silica particles obtained by a vaporized metal combustion method (VMC method: Vaporized Metal Combustion Method). Vaporized metal combustion method (VMC method) is a method for obtaining silica particles which includes burning a combustion improver (hydrocarbon gas or the like) with a burner in an oxygen-containing atmosphere to form a chemical flame and introducing a metallic silica into the chemical flame in an amount sufficient to form a dust cloud so as to cause vaporized metal combustion.

In an embodiment, the silica particles as a raw material are silica particles obtained by a melting method. The melting method is a method for obtaining silica particles which includes introducing silica into a flame to be melted and then cooling the particles.

The type of silica particles for use is not particularly limited, and for example, surface-modified silica particles may be used. For example, the silica particles may have a cationic group(s). Preferred examples of the silica particles having a cationic group(s) may include silica particles with an amino group(s) immobilized to the surface. Examples of production method of the silica particles having a cationic group(s) may include a method for immobilizing a silane coupling agent having an amino group such as aminoethyl trimethoxy silane, aminopropyl trimethoxy silane, aminoethyl triethoxy silane, aminopropyl triethoxy silane, aminopropyl dimethyl ethoxy silane, aminopropyl methyl diethoxy silane, or aminobutyl triethoxy silane on the surface of abrasive grains as described in Japanese Patent Laid-Open No. 2005-162533. Thereby, the silica particles with an amino group(s) immobilized to the surface (amino group-modified silica particles) can be obtained.

The silica particles may have an anionic group(s). Preferred examples of the silica particles having an anionic group(s) may include silica particles with an anionic group(s) such as a carboxylic acid group(s), a sulfonic acid group(s), a phosphonic acid group(s) or an aluminic acid group(s) immobilized to the surface. A production method of the silica particles having an anionic group(s) is not particularly limited, and examples thereof may include a method for reacting a silane coupling agent having an anionic group at its end with silica particles.

As the specific examples thereof, a sulfonic acid group(s) may be immobilized to silica particles, for example, by a method described in “Sulfonic acid-functionalized silica through quantitative oxidation of thiol groups”, Chem. Commun. 246-247 (2003). Specifically, silica particles with a sulfonic acid group(s) immobilized to the surface can be obtained by coupling a silane coupling agent having a thiol group(s) such as 3-mercaptopropyl trimethoxy silane with silica particles, and then oxidizing the thiol group(s) with hydrogen peroxide.

Alternatively, in order to immobilize a carboxylic acid group(s) to silica particles, for example, a method described in “Novel Silane Coupling Agents Containing a Photolabile 2-Nitrobenzyl Ester for Introduction of a Carboxy Group on the Surface of SilicaGel”, Chemistry Letters, 3, 228-229 (2000) may be employed. Specifically, silica particles with a carboxylic acid group(s) immobilized to the surface can be obtained by coupling a silane coupling agent containing a photoreactive 2-nitrobenzyl ester with silica particles, and then performing photoirradiation.

An average particle size (D₅₀) of the silica particles as abrasive grains contained in the polishing composition according to the present embodiment is more than 1.0 μm. With an average particle size (D₅₀) of silica particles of 1.0 μm or less, the polishing removal rate of an object to be polished is insufficient. The average particle size (D₅₀) of silica particles is preferably more than 1.2 μm, more preferably 1.5 μm or more, particularly preferably 1.8 μm or more, and most preferably 2.0 μm or more. The average particle size (D₅₀) of silica particles is preferably 20.0 μm or less, more preferably 15.0 μm or less, particularly preferably 13.0 μm or less, and particularly preferably 12.0 μm or less. In particular, with an average particle size (D₅₀) of silica particles of 3.0 μm or more and 10.0 μm or less (particularly 5.0 μm or more and 8.0 μm or less), residual abrasive grains can be more effectively reduced while maintaining a high polishing removal rate. The average particle size (D₅₀) of silica particles is preferably more than 1.2 μm and 20 μm or less, more preferably 1.5 μm or more and 15.0 μm or less, particularly preferably 1.8 μm or more and 13.0 μm or less, and most preferably 2.0 μm or more and 12.0 μm or less. Within the range, the polishing removal rate of an object to be polished can be improved, and further, the residual abrasive grains on the surface of an object to be polished after polishing can be reduced, so that compatibility between improvement of the polishing removal rate and reduction of the residual abrasive grains can be achieved with good balance. Further, within the range, a smaller particle size is suitable for reducing residual abrasive grains, and a larger particle size is suitable for improving the polishing removal rate. The average particle size (average secondary particle size) of silica particles is a particle size (D₅₀) indicating a 50% cumulative frequency from the small-particle-size end in a volume-based particle size distribution. Here, the average particle size (D₅₀) of silica particles can be determined by a dynamic light scattering method, a laser diffraction method, a laser scattering method, a pore electrical resistance method or the like. Specifically, the value determined by the measurement method described in the following Examples is employed.

The particle size D₁₀ of silica particles as abrasive grains contained in the polishing composition according to the present embodiment is preferably more than 1.2 μm, more preferably 1.5 μm or more, particularly preferably 1.8 μm or more, and most preferably 2.0 μm or more. The particle size D₁₀ of silica particles is preferably 10.0 μm or less, more preferably 8.0 μm or less, particularly preferably 5.0 μm or less, and particularly preferably 4.0 μm or less. With a particle size D₁₀ of silica particles in the range, the residual abrasive grains can be more effectively reduced, while maintaining a high polishing removal rate. The particle size D₁₀ of silica particles is preferably more than 1.2 μm and 10 μm or less, more preferably 1.5 μm or more and 8.0 μm or less, particularly preferably 1.8 μm or more and 5.0 μm or less, and most preferably 2.0 μm or more and 4.0 μm or less. With a particle size D₁₀ of silica particles in the range, the polishing removal rate of an object to be polished can be improved, and the residual abrasive grains on the surface of the object to be polished can be reduced, so that compatibility between improvement of the polishing removal rate and reduction of the residual abrasive grains can be achieved with good balance. The particle size D₁₀ of silica particles is a particle size D₁₀ indicating a 10% cumulative frequency from the small-particle-size end in a volume-based particle size distribution. Here, the particle size D₁₀ of silica particles can be determined by a dynamic light scattering method, a laser diffraction method, a laser scattering method, a pore electrical resistance method or the like. Specifically, the value determined by the measurement method described in the following Examples is employed.

The silica particles as abrasive grains contained in the polishing composition according to the present embodiment have a circularity of primary particles (hereinafter, also referred to simply as “circularity”) of 0.90 or more. If the silica particles have a circularity of primary particles of less than 0.90, the silica particles stick in the surface of an object to be polished during polishing due to irregularities on the surface of the abrasive grains, so that residual abrasive grains on the surface increases excessively after polishing. The silica particles have a circularity of primary particles of preferably 0.92 or more, more preferably 0.95 or more, and particularly preferably more than 0.95. For example, the silica particles have a circularity of primary particles of preferably 0.92 or more and 1.00 or less, more preferably 0.95 or more and 1.00 or less, and particularly preferably more than 0.95 and 1.00 or less. Within the range, the polishing removal rate of an object to be polished can be improved, residual abrasive grains on the surface of an object to be polished after polishing can be reduced, so that compatibility between the improvement of the polishing removal rate and the reduction of the residual abrasive grains can be achieved with good balance. In the present description, the circularity of the primary particles of the silica particles is determined by a method described in the following Examples to give a value down to the third decimal place which is then rounded to the second decimal place. A circularity closer to 1 (1.00) is more approximate to a true sphere. Accordingly, a circularity closer to 1 (1.00) indicates that a ratio of particles approximate to a true sphere is higher in the silica particles. Use of the particles more approximate to a true sphere may allow to easily obtain the effects described above.

Here, although the zeta potential of the silica particles as abrasive grains contained in the polishing composition according to the present embodiment is required to have a positive product with the zeta potential of an anticaking agent to be described below without particular limitation, the absolute value of the zeta potential is, for example, 0.5 mV or more. The absolute value of the zeta potential of the silica particles is preferably 10 mV or more, more preferably 20 mV or more, still more preferably 30 mV or more, particularly preferably 40 m V or more, and most preferably 45 mV or more. The absolute value of the zeta potential of the silica particles is preferably 80 mV or less, more preferably 70 mV or less, still more preferably 65 mV or less, particularly preferably 60 m V or less, and most preferably 55 mV or less. With an absolute value of the zeta potential of the silica particles within the range, redispersion properties of the sediment occurring in the polishing composition are further excellent, so that the residual abrasive grains on the surface of an object to be polished after polishing can be further reduced.

In an embodiment, the silica particles have a new Mohs hardness of 5 or more and 9 or less. Such a hardness allows compatibility between improvement of the polishing removal rate and reduction of the residual abrasive grains to be achieved with good balance.

One type of silica particles may be used alone, or two or more types thereof may be used in combination.

A concentration (content) of the silica particles in the polishing composition according to the present embodiment is not particularly limited. In the case of a polishing composition to be directly used as polishing liquid for polishing an object to be polished (typically a polishing liquid in a slurry state, which may be also referred to as working slurry or polishing slurry), the concentration (content) of the silica particles relative to the total mass of the polishing composition is preferably 0.05 mass % or more, more preferably 0.1 mass % or more, still more preferably more than 0.1 mass %, and particularly preferably 0.2 mass % or more. The more the concentration (content) of the silica particles is, the more improved the polishing removal rate is. Also, the concentration (content) of the silica particles relative to the total mass of the polishing composition is preferably 20 mass % or less, more preferably 15 mass % or less, still more preferably 10 mass % or less, furthermore preferably less than 10 mass %, and particularly preferably 8 mass % or less. Within the range, the occurrence of defects such as residual abrasive grains can be further reduced. For example, the concentration (content) of the silica particles relative to the total mass of the polishing composition is preferably 0.05 mass % or more and 20 mass % or less, more preferably 0.1 mass % or more and 15 mass % or less, still more preferably more than 0.1 mass % and 10 mass % or less, furthermore preferably more than 0.1 mass % and less than 10 mass %, and particularly preferably 0.2 mass % or more and 8 mass % or less. Within the range, the polishing removal rate of an object to be polished can be improved. Also, further excellent redispersion properties of the sediment occurring in the polishing composition are obtained, so that residual abrasive grains on the surface of an object to be polished after polishing can be reduced. Herein, in the case of using two or more types of silica particles, the concentration (content) of the silica particles means a total amount of all types of silica particles.

A concentration (content) of the silica particles in a polishing composition to be diluted for use in polishing (i.e., concentrate, undiluted liquid for working slurry) is usually 30 mass % or less, and more preferably 25 mass % or less, from the viewpoints of storage stability, filterability and the like. Further, from the viewpoint of taking advantage of a concentrate, the concentration (content) of the silica particles is preferably 1 mass % or more, and more preferably 4 mass % or more.

The abrasive grains are substantially composed of silica particles having an average particle size (D₅₀) of more than 1.0 μm and a circularity of primary particles of 0.90 or more. Here, “abrasive grains are substantially composed of silica particles according to the present embodiment” means that a total content of the silica particles contained in a polishing composition relative to the total content of abrasive grains contained in the polishing composition is more than 99 mass % (upper limit: 100 mass %). Preferably, the abrasive grains are composed of the silica particles according to the present embodiment alone (total content of the silica particles according to the present embodiment relative to the whole abrasive grains is 100 mass %).

### [Anticaking Agent]

The anticaking agent contained in the polishing composition according to the present embodiment includes inorganic particles different from the silica particles contained as abrasive grains. In other words, the anticaking agent includes inorganic particles other than silica particles having an average particle size (D₅₀) of more than 1.0 μm and a circularity of primary particles of 0.90 or more. In the case of sedimentation of the solid content (for example, abrasive grains) in a polishing composition, the anticaking agent has a function of maintaining fluidity of the sediment. Accordingly, use of the anticaking agent allows the sediment occurring in the polishing composition after storage to be easily redispersed into a liquid part by shaking or stirring.

The anticaking agent may include inorganic particles other than silica particles having an average particle size (D₅₀) of more than 1.0 μm and a circularity of primary particles of 0.90 or more, and is preferably inorganic particles having an average particle size (D₅₀) of less than 1.0 μm. The anticaking agent may be used alone or in combination of two or more. As the anticaking agent, a synthetic product or a commercially available product may be used.

Examples of the inorganic particles for use as anticaking agent include metal oxides such as silica (excluding silica particles having an average particle size (D₅₀) of more than 1.0 μm and a circularity of primary particles of 0.90 or more), alumina, zirconia and titania. Alumina is preferred in order to efficiently achieve the desired effect of the present invention. Preferred examples of the type of alumina include xx-alumina, intermediate alumina (γ-alumina, δ-alumina and θ-alumina), colloidal alumina and fumed alumina, any of which is suitably used without particular limitation. Among them, colloidal alumina and fumed alumina are preferred, and colloidal alumina is more preferred. Accordingly, in an embodiment of the present invention, the anticaking agent includes colloidal alumina. In such an embodiment, the fluidity of the sediment in an object to be polished is maintained, so that good redispersion properties can be exhibited.

The average particle size of the anticaking agent is preferably 900 nm or less, more preferably 800 nm or less, still more preferably 700 nm or less, particularly preferably 600 nm or less, and most preferably 500 nm or less. Further, the average particle size of the anticaking agent is preferably 1 nm or more, more preferably 5 nm or more, still more preferably 10 nm or more, particularly preferably 15 nm or more, and most preferably 20 nm or more. With an average particle size of the anticaking agent within the range, even in the case of sedimentation of the solid content (abrasive grains) in the polishing composition, the sediment can maintain fluidity, so that better redispersion properties can be exhibited. The average particle size of the anticaking agent is determined as follows. The anticaking agent is photographed by a scanning electron microscope (SEM) (product name: SU8000, manufactured by Hitachi High-Tech Corporation) or a scanning transmission electron microscope STEM (product name: HD-2700, manufactured by Hitachi High-Tech Corporation), and the resulting SEM image is analyzed using an image analysis software (“WinROOF 2018”, manufactured by Mitani Corporation). In more detail, from the particles present in the SEM image, 30 pieces of particles are randomly selected as samples for measurement of the particle size of each particle. Average thereof is calculated and the average value is defined as the average particle size of the anticaking agent.

In the polishing composition according to the present embodiment, the average particle size of the anticaking agent may be 450 nm or less, 400 nm or less, 350 nm or less, 300 nm or less, 250 nm or less, 200 nm or less, 150 nm or less, 100 nm or less, or 50 nm or less. In an embodiment, the anticaking agent includes alumina particles having an average particle size of 500 nm or less. Further, in an embodiment, the anticaking agent includes alumina particles having an average particle size of 200 nm or less.

Here, the zeta potential of the anticaking agent has a relation in which the product with the zeta potential of the abrasive grains described above (silica particles) is positive. In other words, in the polishing composition according to the present embodiment, the zeta potential of the abrasive grains and the zeta potential of the anticaking agent have the same sign. For example, in the polishing composition according to the present embodiment, in the case where the zeta potential of the abrasive grains is positive, the zeta potential of the anticaking agent is also positive, while in the case where the zeta potential of the abrasive grains is negative, the zeta potential of the anticaking agent is also negative. Since the zeta potential of the abrasive grains and the zeta potential of the anticaking agent have such a relation in the polishing composition, fluidity of the sediment occurring in the polishing composition left to stand still can be maintained. For example, it is conceivable that only by shaking or stirring the polishing composition with a sediment, the sediment can be redispersed into a liquid part. Although the mechanism of such an effect of the present invention is presumed as follows, the mechanism is based on a presumption only, so that the scope of the present invention is not limited thereby.

In the case where solid-liquid separation occurs in a polishing composition, it is presumed that abrasive grains and an anticaking agent make sediment. In the case where the zeta potential of the abrasive grains and the zeta potential of the anticaking agent have the same sign, repulsive force works between the abrasive grains and the anticaking agent, so that these particles are stacked in a bulky state to make a sediment. In this case, each particle that forms the sediment has fluidity, and it is presumed that the sediment is redispersed into a liquid part only by shaking or stirring the polishing composition with the sediment. On the other hand, in the case where the zeta potential of the abrasive grains and the zeta potential of the anticaking agent have a different sign, an attractive force works between the abrasive grains and the anticaking agent, so that these particles are stacked in close to each other to make a sediment. In this case, each particle that forms the sediment loses fluidity, and it is presumed that the sediment is not untangled only by shaking or stirring the polishing composition with the sediment, so that the sediment cannot be redispersed into a liquid part. Further, the present inventor has found that the residual abrasive grains tend to be reduced with improvement of the redispersion properties of the polishing composition. The reason is presumed that the aggregation state of the sediment occurring in the polishing composition has an effect on the residual abrasive grains. In the case where a polishing composition has good redispersion properties, the fluidity of the sediment is maintained, so that it is presumed that the abrasive grains maintain a certain degree of distance from each other even during polishing. On the other hand, a polishing composition having poor redispersion properties maintains no fluidity of the sediment. Accordingly, the abrasive grains come close to each other during polishing, so that it is presumed that such an aggregate of the abrasive grains as irregularly shaped particle tends to stick into a substrate. It has been found that the polishing composition of the present invention exhibits also unpredictable effect of good results on the residual abrasive grains through improvement of the redispersion properties.

The zeta potential of the anticaking agent is not particularly limited as long as the product with the zeta potential of the abrasive grains (silica particles) described above is positive, and the absolute value thereof is, for example, 0.5 mV or more. The absolute value of the zeta potential of the anticaking agent is preferably 1 mV or more, more preferably 2 mV or more, still more preferably 3 mV or more, particularly preferably 4 m V or more, and most preferably 4.5 mV or more. The absolute value of the zeta potential of the silica particles is preferably 50 mV or less, more preferably 40 mV or less, still more preferably 30 mV or less, particularly preferably 20 mV or less, and most preferably 15 mV or less. With an absolute value of the zeta potential of the anticaking agent within the range, the good redispersion properties of the sediment occurring in the polishing composition are further improved and the residual abrasive grains on the surface of an object to be polished after polishing can be further reduced.

The product of the zeta potentials of abrasive grains and an anticaking agent contained in a polishing composition can be determined to be positive, for example, as follows. The abrasive grains and the anticaking agent contained in a polishing composition have differences in particle size, specific gravity (density) and the like. Accordingly, through centrifugation or the like, abrasive grains and anticaking agent contained in the polishing composition are separated into two solutions, each of which contains one type of particles in a greater amount, and the zeta potential of each of the solutions is measured. In the case where the zeta potentials of the two solutions have electric charges with the same sign, it can be determined that the product of the zeta potentials of the abrasive grains and the anticaking agent contained in the polishing composition is positive. The conditions for separating into two solutions, each of which contains one of the abrasive grains and the anticaking agent contained in the polishing composition in a greater amount, may be appropriately adjusted corresponding to the type of the abrasive grains and the anticaking agent, including, for example, a centrifugation method at RCF 85 (×g) for 1 hour. Alternatively, the polishing composition is dried, and from the dried product obtained, inorganic particles, organic particles, etc., are identified using a microscope or the like. Through further classification based on the particle size, specific gravity, etc., each of the possible particles of abrasive grains and anticaking agent can be obtained. An aqueous dispersion of each of the possible particles of abrasive grains and anticaking agent (for example, an aqueous dispersion having a pH of 7.0 or more and 11.0 or less) is prepared and then subjected to measurement of zeta potential. In the case where the zeta potentials of the abrasive grains and the anticaking agent have electric charges with the same sign, it can be determined that the product of the zeta potentials of the abrasive grains and the anticaking agent contained in the polishing composition is positive. Further, in the case where inorganic particles other than abrasive grains and an anticaking agent are contained, the abrasive grains and the anticaking agent can be identified from the particle size, specific gravity (density), particle shape, constituent elements, etc.

Here, the product of the zeta potential of the anticaking agent and the zeta potential of the abrasive grains (silica particles) is not particularly limited as long as it is positive, and for example, preferably 3 or more, more preferably 5 or more, still more preferably 50 or more, particularly preferably 100 or more, and most preferably 150 or more. The product of the zeta potential of the anticaking agent and the zeta potential of the abrasive grains (silica particles) is preferably 1000 or less. With a product of the zeta potential of the anticaking agent and the zeta potential of the abrasive grains within the range, the good redispersion properties of the sediment occurring in the polishing composition are further improved and the residual abrasive grains on the surface of an object to be polished after polishing can be further reduced.

The anticaking agent has a specific gravity of, preferably 1.2 or more, more preferably 1.5 or more, still more preferably 1.8 or more, particularly preferably 2.0 or more, and most preferably 2.2 or more. The specific gravity of the anticaking agent is preferably 4.5 or less. With a specific gravity of the anticaking agent within the range, the good redispersion properties of the sediment occurring in the polishing composition are further improved and the residual abrasive grains on the surface of an object to be polished after polishing can be further reduced. In the present description, the specific gravity is measured in accordance with JIS-R-9301-2-1 (1999).

A concentration (content) of the anticaking agent in the polishing composition of the present embodiment is not particularly limited, and may be appropriately selected corresponding to the desired redispersion properties of the polishing composition after storage. In both of the case of a polishing composition that is directly used as polishing liquid for polishing an object to be polished (typically, a polishing liquid in a slurry state, which is also referred to as working slurry or polishing slurry), and the case of a polishing composition that is diluted for use in polishing (i.e., concentrate, undiluted solution for working slurry), the mass of the anticaking agent may be selected relative to the mass of the abrasive grains. For example, the typical content of the anticaking agent relative to the total mass (100 mass %) of the abrasive grains is preferably 20 mass % or less, more preferably 15 mass % or less, still more preferably 10 mass % or less, particularly preferably 5 mass % or less, and most preferably 3 mass % or less. Also, the content of the anticaking agent relative to the total mass (100 mass %) of the abrasive grains is preferably 0.1 mass % or more, more preferably 0.3 mass % or more, still more preferably 0.5 mass % or more, particularly preferably 0.8 mass % or more, and most preferably 1 mass % or more. In other words, the content of the anticaking agent relative to the total mass (100 mass %) of the abrasive grains is preferably 0.1 mass % or more and 20 mass % or less, more preferably 0.3 mass % or more and 15 mass % or less, still more preferably 0.5 mass % or more and 10 mass % or less, particularly preferably 0.8 mass % or more and 5 mass % or less, and most preferably 1 mass % or more and 3 mass % or less. Within the range, the polishing composition after storage can be easily redispersed. In the case of using two or more of anticaking agents, the content of the anticaking agent means a total amount of all the anticaking agents.

### [Dispersing Medium]

The polishing composition according to the present embodiment contains a dispersing medium. The dispersing medium disperses or dissolves each of the components.

It is preferable that the dispersing medium contain water. Further, from the viewpoint of preventing impurities from affecting other components in the polishing composition, it is preferable to use water as pure as possible. Specifically, pure water or ultra-pure water prepared by removing impurity ions through an ion exchange resin and then removing foreign substances through a filter, or distilled water is preferred. Also, as a dispersing medium, an organic solvent or the like may be further included to control dispersibility and the like of other components of the polishing composition.

### [pH Adjusting Agent]

It is preferable that the polishing composition according to an embodiment of the present invention further contain a pH adjusting agent. Through selection of the type and the amount added, the pH adjusting agent can contribute to adjustment of pH of the polishing composition.

The pH adjusting agent is not particularly limited as long as it is a compound having a pH adjusting function, and a known compound may be used. The pH adjusting agent is not particularly limited as long as it is the one having a pH adjusting function, and examples thereof include an acid and an alkali.

As the acid, any of an inorganic acid and an organic acid may be used. The inorganic acid is not particularly limited, and examples thereof may include sulfuric acid, nitric acid, boric acid, carbonic acid, hypophosphorous acid, phosphorous acid, and phosphoric acid. The organic acid is not particularly limited, and examples thereof may include carboxylic acids such as 1-hydroxyethylidene-1,1-diphophonic acid (HEDP), formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid and lactic acid, and methane sulfonic acid, ethane sulfonic acid and isethionic acid. Among these, organic acids are preferred, and 1-hydroxyethylidene-1,1-diphophonic acid (HEDP), malic acid, citric acid and maleic acid are more preferred. In the case of using an inorganic acid, nitric acid, sulfonic acid and phosphoric acid are preferred.

The alkali is not particularly limited, and examples thereof may include hydroxides of alkali metal such as potassium hydroxide, ammonia, quaternary ammonium salts such as tetramethylammonium and tetraethylammonium, and amines such as ethylenediamine and piperazine. Among these, potassium hydroxide and ammonia are preferred.

The pH adjusting agents may be used alone or in combination of two or more.

A content of the pH adjusting agent is not particularly limited, preferably being an amount allowing the pH value to be controlled in the preferred range described later.

### [Other Components]

The polishing composition according to the present embodiment may further contain a known component such as abrasive grains other than the ones described above, a chelating agent, a thickener, an oxidizing agent, a dispersing agent, a surface protecting agent, a wetting agent, a surfactant, an anticorrosive (rust inhibitor), an antiseptic agent, and an antifungal agent, within a range not impairing the effect of the present invention. A content of the other components may be appropriately set depending on the purpose of addition.

### [Ph]

In the case of a polishing composition to be directly used as polishing liquid for polishing an object to be polished, the pH of the polishing composition according to the present embodiment is preferably 7.0 or more. The pH of the polishing composition according to the present embodiment is preferably 11.0 or less, more preferably 10.5 or less, and particularly preferably 10.0 or less. In other words, the pH of the polishing composition according to the present embodiment is preferably 7.0 or more and 11.0 or less, more preferably 7.0 or more and 10.5 or less, and particularly preferably 7.0 or more and 10.0 or less. Within the range, the product of the zeta potentials of silica particles as abrasive grains and the anticaking agent is easily controlled to be positive, contributing improvement in redispersion properties of the polishing composition. Further, compatibility between improvement of polishing removal rate and reduction of residual abrasive grains can be achieved with good balance. In the present description, the pH of the polishing composition is determined by the measurement method described in the following Examples.

In the case where the polishing composition is directly used as polishing liquid for polishing an object to be polished, according to an embodiment, the pH of the polishing composition is preferably 4.0 or less, more preferably less than 4.0, and still more preferably 3.5 or less. Further, according to an embodiment, the pH of the polishing composition is preferably 1.0 or more, more preferably more than 1.0, still more preferably 1.5 or more, and particularly preferably more than 1.5. In other words, according to an embodiment, the pH of the polishing composition is preferably 1.0 or more and 4.0 or less, more preferably more than 1.0 and less than 4.0, still more preferably 1.5 or more and 3.5 or less, and particularly preferably more than 1.5 and 3.5 or less. Within the range, compatibility between improvement of polishing removal rate and reduction of residual abrasive grains can be achieved with good balance. In the present description, the pH of the polishing composition is determined by the measurement method described in the following Examples.

In the case of a polishing composition which is diluted for use in polishing (i.e., concentrate), the appropriate pH of the polishing composition is 7.0 or more, preferably more than 7.0, and more preferably 7.5 or more. The appropriate pH of the polishing composition is 11.0 or less, preferably less than 11.0, and more preferably 10.5 or less.

In the case of a polishing composition that is diluted for use in polishing (i.e., concentrate), according to an embodiment, the appropriate pH of the polishing composition is 1.0 or more, preferably more than 1.0, and more preferably 1.5 or more. The appropriate pH of the polishing composition is 7.5 or less, preferably less than 5.5, and more preferably less than 4.5.

### <Method for Producing Polishing Composition>

A method for producing (method for preparing) the polishing composition is not particularly limited, and for example, a production method including providing abrasive grains and an anticaking agent, and stirring and mixing the same with a dispersing medium (preferably water) and optionally other components may be appropriately employed. Thus, another embodiment of the present invention relates to a method for producing a polishing composition including selecting silica particles having an average particle size (D₅₀) of more than 1.0 μm and a circularity of primary particles of 0.90 or more as abrasive grains, selecting inorganic particles different from the abrasive grains as anticaking agent, and mixing the abrasive grains and the anticaking agent with a dispersing medium. The abrasive grains, the anticaking agent, the dispersing medium and the other components are the same as those described in the item <Polishing composition>, and so the description is omitted here.

In an embodiment of the present invention, silica particles having an average particle size (D₅₀) of more than 1.0 μm and a circularity of primary particles of 0.90 or more can be obtained by selecting silica particles satisfying the specific conditions from commercially available silica particles. In an embodiment of the present invention, silica particles having an average particle size (D₅₀) of more than 1.0 μm and a circularity of primary particles of 0.90 or more can be obtained by producing silica particles under conditions that they satisfy the specific conditions. In an embodiment of the present invention, silica particles having an average particle size (D₅₀) of more than 1.0 μm and a circularity of primary particles of 0.90 or more can be obtained by controlling silica particles not satisfying the specific conditions to satisfy the specific conditions. On this occasion, a known control method may be used in the same manner or in an appropriately modified manner. For example, in the case of a vaporized metal combustion method, a method for controlling a particle size, a supply rate, a mixing ratio with oxygen, or the like of metallic silicon may be applied.

The silica particles selected as abrasive grains and the inorganic particles selected as anticaking agent as defined herein, are stirred and mixed with a dispersing medium (preferably water), and, optionally other components (for example, pH adjusting agent) to produce the polishing composition. On this occasion, an order of mixing the respective components is not particularly limited. For example, in the case where the polishing composition contains abrasive grains, an anticaking agent and a dispersing medium, the polishing composition may be prepared by: feeding abrasive grains, an anticaking agent and other components collectively, and optionally adding a pH adjusting agent thereto so as to obtain a desired pH; feeding abrasive grains and an anticaking agent into a dispersing medium, and optionally adding a pH adjusting agent thereto so as to obtain a desired pH; feeding abrasive grains and an anticaking agent into a dispersing medium in this order, and optionally adding a pH adjusting agent thereto so as to obtain a desired pH; feeding an anticaking agent and abrasive grains into a dispersing medium in this order, and optionally adding a pH adjusting agent thereto so as to obtain a desired pH, or the like. A temperature at which the respective components are stirred and mixed is not particularly limited, and preferably 10° C. or more and 40° C. or less. Heating may be performed to increase a dissolution rate. A mixing time is also not particularly limited.

### <Object to be Polished>

An object to be polished by the polishing composition according to the present embodiment is not particularly limited. It is preferable that the object to be polished contains a resin and a filler. Thus, in a preferred embodiment of the present invention, the polishing composition is used to polish an object to be polished containing a resin and a filler. When the polishing composition according to the present embodiment including the specific silica particles as defined above as abrasive grains is used for polishing an object to be polished containing a resin and a filler, polishing proceeds so that the filler and the resin around the filler are peeled off at the same time, and thus a specifically high polishing removal rate can be obtained in comparison with other abrasive grains for polishing. Further, in the case of polishing a portion of resin containing a filler and a portion of metal such as copper at the same time, the abrasive grains can be suppressed or prevented from sticking into a metal surface (damage to the metal can be suppressed or prevented). Thus, the residual abrasive grains on the surface of the object to be polished after polishing can be reduced. Accordingly, in polishing of an object to be polished containing a resin and a filler, the compatibility between high polishing removal rate and reduction of residual abrasive grains on a surface of an object to be polished after polishing can be achieved. On the other hand, when alumina particles (pulverized alumina particles) generally used as abrasive grains for polishing are used, polishing proceeds so that the filler and the resin are scraped off in sequence from the surface. Further, in the case of polishing a portion of resin containing a filler and a portion of metal such as copper at the same time, the abrasive grains tend to stick into the portion of metal. Thus, the residual abrasive grains on the surface after polishing tends to increase.

Hereinafter, an embodiment in which an object to be polished contains a resin and a filler will be described in detail, though the present invention is not limited to the following embodiment.

The resin is not particularly limited, and examples thereof may include an acrylic resin such as polymethyl (meth)acrylate, a methylmethacrylate-methylacrylate copolymer, and a urethane (meth)acrylate resin; an epoxy resin; an olefin resin such as ultra-high molecular weight polyethylene (UHPE); a phenol resin; a polyamide resin (PA); a polyimide resin (PI); a polyester resin such as polyethylene terephthalate (PET), polybutylene terephthalate (PBT), and an unsaturated polyester resin; a polycarbonate resin (PC); a polyphenylene sulfide resin (PPS); a polystyrene resin such as syndiotactic polystyrene (SPS); a polynorbornene resin; polybenzoxazole (PBO); polyacetal (POM); modified polyphenylene ether (m-PPE); amorphous polyacrylate (PAR); polysulfone (PSF); polyether sulfone (PES); polyether ether ketone (PEEK); polyether imide (PEI); a fluorine resin; and a liquid crystal polymer (LCP). In the present description, “(meth)acrylic acid” refers to acrylic acid or methacrylic acid, or both acrylic acid and methacrylic acid. In the same manner, in the present description, “(meth)acrylate” refers to acylate or methacrylate, or also both of acrylate and methacrylate. Among these, from the viewpoint of processability, a resin having a cyclic molecular structure is preferred. Thus, in a preferred embodiment of the present invention, the resin has a cyclic molecular structure. As the resin having such a cyclic molecular structure, an epoxy resin, a polycarbonate resin, or a polyphenylene sulfide resin is preferably used. The resins may be used alone, or in combination of two or more. Alternatively, the resin may be cured by a curing agent.

A material to constitute the filler is not particularly limited, and examples thereof may include glass, carbon, calcium carbonate, magnesium carbonate, barium sulfate, magnesium sulfate, aluminum silicate, titanium oxide, alumina, zinc oxide, silica (silicon dioxide), kaolin, talc, glass beads, sericite active white clay, bentonite, aluminum nitride, polyester, polyurethane and rubber. Among these, from the viewpoint of processability, glass and silica are preferred, and silica is particularly preferred.

Examples of a shape of the filler may include a powder form, a spherical form, a fiber form and a needle form. Among these, a spherical form and a fiber form are preferred, and a spherical form is more preferred from the viewpoint of processability. A size of the filler is not particularly limited. For example, in the case of filler in a spherical form, the average particle size is, for example, 0.01 μm or more and 50 μm or less, and preferably 1.0 μm or more and 6.5 μm or less. For the average particle size, 200 fillers are selected at random from an image of an object to be polished photographed by a scanning electron microscope (SEM) (product name: SU8000, manufactured by Hitachi High-Tech Corporation), to measure each of the particle size, and the average thereof is presumed to be the average particle size. In the case of filler in a fiber form, the average major diameter is for example, 100 μm or more and 300 μm or less, and preferably 150 μm or more and 250 μm or less, and the average minor diameter is for example, 1 μm or more and 30 μm or less, and preferably 10 μm or more and 20 μm or less. Here, 200 fillers are selected at random from an image of an object to be polished photographed by a scanning electron microscope (SEM) (product name: SU8000, manufactured by Hitachi High-Tech Corporation), to measure each of the major diameter and each of the minor diameter, respectively, and the averages thereof are presumed to be the average major diameter (μm) and the average minor diameter (μm), respectively.

Although any combination of silica particles as abrasive grains and fillers may be employed, it is preferable that the size (average particle size) of silica particles as abrasive grains be larger than the size (average particle size) of the fillers. Thus, in preferred embodiment of the present invention, in the case where an object to be polished contains a resin and a filler, the average particle size (D₅₀) of the silica particles as abrasive grains is larger than the average particle size of the filler. In the case where the average particle size (D₅₀) of silica particles is larger than the average particle size of the filler, the polishing removal rate improves. Accordingly, such a relation between the average particle size (D₅₀) of silica particles and the average particle size of the filler allows compatibility between improvement of the polishing removal rate and reduction of the residual abrasive grains to be achieved more easily. In the embodiment, although the relation between the size of silica particles and the size of filler is not particularly limited, a ratio of the average particle size (D₅₀) of the abrasive grains to the average particle size of the filler is preferably more than 1 and 15 or less, more preferably 1.5 or more and less than 10.0, and still more preferably more than 1.6 and less than 7.0. In the above, the average particle size of filler means an average particle size for spherical filler, and an average minor diameter for fibrous filler.

In the case where the abrasive grains (silica particles) have a large average particle size, each particle of the sediment tends to lose fluidity in the polishing composition, and the sediment is not untangled only by shaking or stirring the polishing composition with the sediment, so that it is difficult to redisperse the sediment into a liquid part. Accordingly, in the case of polishing an object to be polished containing a resin and a filler, the average particle size of abrasive grain enlarged corresponding to the average particle size of the filler cannot be used for polishing, because the sediment formed in the polishing composition cannot be redispersed. Therefore, compatibility between improvement of the polishing removal rate and reduction of the residual abrasive grains is difficult. On the other hand, the polishing composition of the present embodiment allows the sediment to maintain the fluidity to exhibit better redispersion properties even in the case of sedimentation of the solid content (abrasive grains) in the polishing composition. In other words, in the case of polishing an object to be polished containing a resin and a filler, even with an enlarged average particle size of the abrasive grains, the sediment can be redispersed, which is favorable for compatibility between improvement of the polishing removal rate and reduction of residual abrasive grains as well. From these reasons, the polishing composition of the present embodiment can be suitably used for polishing of sealing materials and insulating materials used in an electronic device such as semiconductor.

The fillers may be used alone, or in combination of two or more.

Further, the object to be polished may contain a material different from the resin and filler in a surface to be polished in addition to them. Examples of the material may include copper (Cu), aluminum (Al), tantalum (Ta), tantalum nitride (TaN), titanium (Ti), titanium nitride (TiN), nickel (Ni), ruthenium (Ru), cobalt (Co), tungsten (W) and tungsten nitride (WN).

The object to be polished may be prepared from a resin and a filler, or may be prepared from a commercial product. Examples of the commercial product may include interlayer insulation materials “Ajinomoto Build-up Film (registered trademark)” (ABF) GX13, GX92, GX-T31 and GZ41 (all manufactured by Ajinomoto Fine-Techno Co., Inc.); a polycarbonate (PC) resin “Panlite (registered trademark)”, glass fiber reinforced grade (both manufactured by Teijin Limited); and GF reinforced Durafide (registered trademark) PPS, and GF-inorganic filler reinforced Durafide (registered trademark) PPS (both manufactured by Polyplastics Co., Ltd.).

### <Polishing Method>

Another embodiment of the present invention relates to a polishing method including a step of polishing an object to be polished with the polishing composition. Preferred examples of the object to be polished according to the present embodiment are the same described in <Object to be polished> above. For example, it is preferable to polish an object to be polished containing a resin and a filler in a surface to be polished. Thus, the preferred embodiment of the polishing method according to the present embodiment includes a step of polishing an object to be polished containing a resin and a filler with the polishing composition.

Polishing an object to be polished with the polishing composition may be performed using an apparatus and conditions for use in usual polishing. Examples of the typical polishing apparatus may include a single side polishing machine and a double side polishing machine. In a single side polishing machine, an object to be polished is typically held with a retainer referred to as carrier, and a plate with a polishing pad attached is pressed against one side of the object to be polished and rotated, while the polishing composition is supplied from above, so that the one side of the object to be polished is polished. In a double side polishing machine, an object to be polished is typically held with a retainer referred to as carrier, and platens with a polishing pad attached are pressed against opposing surfaces of the object to be polished and rotated in the opposing directions, while the polishing composition is supplied from above, so that both sides of the object to be polished are polished. On this occasion, polishing is performed through a physical action caused by friction between the polishing pad together with the polishing composition and the object to be polished, and through a chemical action on the object to be polished caused by the polishing composition. As the polishing pad, a porous material of nonwoven fabric, polyurethane, suede or the like may be used without particular limitation. It is preferable that the polishing pad be processed such that a polishing liquid is accumulated.

Examples of the polishing conditions may include polishing load, rotation speed of plate, rotation speed of carrier, flow rate of polishing composition, and polishing time. Although these polishing conditions are not particularly limited, for example, a polishing load per unit area of the object to be polished is preferably 0.1 psi (0.69 kPa) or more and 10 psi (69 kPa) or less, more preferably 0.5 psi (3.5 kPa) or more and 8.0 psi (55 kPa) or less, and still more preferably 1.0 psi (6.9 kPa) or more and 6.0 psi (41 kPa) or less. In general, the more the load is, the more the friction force by abrasive grains is, so that the mechanical processing force is improved. As a result, the polishing removal rate increases. Within the ranges, a sufficient polishing removal rate can be achieved, while damage to an object to be polished and occurrence of defects such as surface scratches caused by the load can be suppressed. It is preferable that a rotation speed of plate and a rotation speed of carrier be 10 rpm (0.17 s⁻¹) or more and 500 rpm (8.3 s⁻¹) or less. A supply rate of polishing composition may be a supply rate (flow rate) at which the polishing composition covers the whole of an object to be polished, and may be adjusted depending on the conditions such as the size of the object to be polished. Also, a method for supplying the polishing composition to a polishing pad is not particularly limited, and, for example, a continuous supply method with use of a pump or the like may be employed. Also, although a processing time is not particularly limited as long as desired processing results are obtained, a less time resulting from a high polishing removal rate is preferred.

Further, another embodiment of the present invention relates to a production method of a polished object, including a step of polishing an object to be polished by the polishing method as defined herein. Preferred examples of the object to be polished according to the embodiment is the same described in <Object to be polished>. As a preferred example, there may be mentioned a production method for an electronic circuit board including polishing an object to be polished including a resin and a metal by the polishing method as defined herein.

Although the embodiments of the present invention have been described in detail, the description is explanatory or exemplary, and not limited. It is obvious that the scope of the present invention should be interpreted according to the claims.

The present invention includes the following aspects and embodiments.
[1] A polishing composition comprising abrasive grains, an anticaking agent, and a dispersing medium, wherein the abrasive grains are silica particles having an average particle size (D₅₀) of more than 1.0 μm and a circularity of primary particles of 0.90 or more, the anticaking agent comprises inorganic particles different from the abrasive grains, and the product of the zeta potential of the abrasive grains and the zeta potential of the anticaking agent is positive.
[2] The polishing composition according to item [1], wherein the anticaking agent comprises inorganic particles having an average particle size (D₅₀) of 500 nm or less.
[3] The polishing composition according to item [1] or [2], wherein the anticaking agent comprises alumina particles having an average particle size (D₅₀) of 200 nm or less.
[4] The polishing composition according to any one of items [1] to [3], wherein the polishing composition is used for polishing an object to be polished containing a resin and a filler.
[5] The polishing composition according to item [4], wherein the silica particles have an average particle size (D₅₀) larger than an average particle size of the filler.
[6] The polishing composition according to item [5], wherein a ratio of the average particle size (D₅₀) of the silica particles to the average particle size of the filler is more than 1 and 15 or less.
[7] A method for producing a polishing composition containing abrasive grains, a dispersing medium and an anticaking agent, the method comprising: selecting silica particles having an average particle size (D₅₀) of more than 1.0 μm and a circularity of primary particles of 0.90 or more as the abrasive grains; selecting inorganic particles different from the abrasive grains as the anticaking agent; and mixing the silica particles and the anticaking agent with the dispersing medium.
[8] A polishing method comprising polishing an object to be polished containing a resin and a filler by using the polishing composition according to any one of the items [1] to [6].
[9] The method according to the item [8], wherein the resin has a cyclic molecular structure.

### EXAMPLES

The present invention will be described in more detail with the following Examples and Comparative Examples. However, the technical scope of the present invention is not limited only to the following Examples. Herein, “%” and “part” mean “mass %” and “part by mass”, respectively.

### <Measurement Method of Physical Property>

[Average Particle Size of Silica Particles (D₅₀) and Particle Size D₁₀]

Silica particles were subjected to measurement using a particle size distribution measuring apparatus (Microtrac particle size distribution measuring apparatus MT3300EX II, manufactured by MicrotracBEL Corp.), to determine a volume-based particle size distribution. In the resulting particle size distribution, a particle size indicating a 50% cumulative frequency from the small-particle-size end was defined as the average particle size of silica particles (D₅₀). In the resulting particle size distribution, a particle size indicating a 10% cumulative frequency from the small-particle-size end was defined as particle size D₁₀ of the silica particles.

### [Average Particle Sizes of Colloidal Alumina Particles and Crystalline Cellulose Particles]

The average particle sizes of colloidal alumina particles and crystalline cellulose particles were determined as follows. The particles were photographed by a scanning electron microscope (SEM) (product name: SU8000, manufactured by Hitachi High-Tech Corporation) or a scanning transmission electron microscope STEM (product name: HD-2700, manufactured by Hitachi High-Tech Corporation), and the resulting SEM image was analyzed using an image analysis software (“WinROOF 2018”, manufactured by Mitani Corporation). In more detail, from the particles present in the SEM image, 500 pieces of particles were randomly selected as samples for measurement of the particle size of each particle. Average thereof was calculated and the average value was defined as the average particle size.

### [Circularity of Silica Particles]

The powder of silica particles was dispersed in methanol and dropped onto an observation substrate. The methanol was evaporated to make a dried sample of silica particles. The sample was photographed by a scanning electron microscope (SEM) (product name: SU8000, manufactured by Hitachi High-Tech Corporation), and the resulting SEM image was analyzed using an image analysis software (“WinROOF 2018”, manufactured by Mitani Corporation). In more detail, from the silica particles present in the SEM image, 30 pieces of silica particles were randomly selected as samples for measurement of circularity of each particle (=4πS/L²; S=Projected area of silica particle, L=Circumference of silica particle). Average thereof was calculated and the average value was defined as the circularity of the silica particles. The circularity of alumina particles was measured in the same manner as described above.

### [Zeta Potential]

The zeta potentials of the abrasive grains and the anticaking agent at each pH were checked by Zetasizer (Zetasizernano ZSP, manufactured by Malvern Panalytrical Ltd.)

[pH]

The pH value of the polishing composition was checked by a pH meter (model number: LAQUA (registered trademark), manufactured by Horiba, Ltd.).

### [Specific Gravity]

The specific gravities of the abrasive grains and anticaking agent were measured in accordance with the method of JIS-R-9301-2-1 (1999).

### EXAMPLES 1 TO 4 AND COMPARATIVE EXAMPLES 1 TO 8

Dry silica particles and dry alumina particles (abrasive grains) described in the following Table 1; colloidal alumina particles, sodium polyacrylate (in Table 1, described as “sodium polyacrylate”) and crystalline cellulose (anticaking agent); and potassium hydroxide and sulfuric acid (pH adjusting agent) were provided. Into distilled water (dispersing medium), the silica particles or alumina particles (abrasive grains) described in Table 1 were mixed to a content of 4 mass % and the colloidal alumina particles, sodium polyacrylate and crystalline cellulose (anticaking agent) were mixed to a content of 0.1 mass % in sequence while stirring. Then, pH was adjusted to the pH described in Table 1 using a pH adjusting agent (potassium hydroxide or sulfuric acid), so that a polishing composition was prepared (mixing temperature: about 25° C., mixing time: about 30 minutes). In Comparative Examples 6 to 8, no crystalline cellulose (anticaking agent) was added.

### Examples 5 to 7

Dry silica particles (abrasive grains) described in the following Table 2; colloidal alumina particles (anticaking agent); and potassium hydroxide (pH adjusting agent) were provided. Into distilled water (dispersing medium), the silica particles (abrasive grains) described in Table 2 were mixed to a content of 4 mass % and the colloidal alumina particles (anticaking agent) described in Table 2 were mixed to a content of 0.1 mass % in sequence while stirring. Then, pH was adjusted to the pH described in Table 1 using a pH adjusting agent (potassium hydroxide), so that a polishing composition was prepared (mixing temperature: about 25° C., mixing time: about 30 minutes). In Examples 5 to 7, using the same polishing composition, the object to be polished (size of the filler contained in the substrate) was changed.

For the polishing compositions obtained as described above, the redispersion properties were examined according to the method described in the following [Redispersion properties]. Further, for the polishing liquid including the polishing composition diluted 20 fold in volume, the polishing removal rate and the number of residual abrasive grains on the surface of the object to be polished after polishing were evaluated according to the methods described in the following [Polishing removal rate] and [Residual abrasive grains on surface], respectively. The results are shown in the following Table 1 and Table 2.

### <Evaluation>

### [Redispersion Properties]

Each of the polishing compositions in an amount of 50 g obtained as described above was placed in a cylindrical bottle (inner diameter: 4 cm) and left to stand still for 30 minutes. The bottle was shaken with an amplitude of 2.5 cm at 200 spm for 72 hours to cause solid-liquid separation. From that state, the bottle was gently rolled over to evaluate the redispersion properties.

### Evaluation Criteria

Good: The sediment collapses when the bottle is rolled over.
Poor: The sediment causes no collapse even when the bottle is rolled over (formation of hard cake)

### [Polishing Removal Rate]

### (Polishing Compositions in Examples 1 to 4 and Comparative Examples 1 to 8)

As an object to be polished, a mixture of an epoxy resin and a filler (spherical silica, average particle size=3.0 μm) with a filler content of 70 mass % was provided (object to be polished 1, density of object to be polished 1:1.9 g/cm³). A copper substrate was also provided (object to be polished 2). Subsequently, the object to be polished 1 and the object to be polished 2 (substrate) were polished with each of the polishing compositions at the same time using the following polishing apparatus and polishing conditions. After completion of polishing, a polishing removal rate of the objects to be polished was evaluated according to the following (Evaluation method of polishing removal rate).

### (Polishing Compositions in Examples 5 to 7)

As an object to be polished, a mixture of an epoxy resin and a filler (spherical silica) having the average particle size described in Table 1 with a filler content of 70 mass % was provided as each of objects to be polished 3A to 3C. The density of the objects to be polished 3A to 3C was 1.9 g/cm³ and the average particle size of fillers contained in the objects to be polished 3A to 3C were as follows. The average particle size of the filler in the object to be polished 3A was 1.0 μm. The average particle size of the filler in the object to be polished 3B was 2.0 μm. The average particle size of the filler in the object to be polished 3C was 3.0 μm. Further, a copper substrate was provided (object to be polished 2). Subsequently, using each of the polishing compositions, any one of the objects to be polished 3A to 3C and (substrate) 2 were polished at the same time using the following apparatus and polishing conditions. After completion of polishing, the polishing removal rate of the objects to be polished was evaluated according to the following (Evaluation method of polishing removal rate).

### (Polishing Apparatus and Polishing Conditions)

Polishing apparatus: small-sized table-top polishing machine (EJ380 IN, manufactured by Engis Japan Corporation)
Diameter of platen: 380 mm
Polishing pad: pad made of rigid polyurethane (IC1010, manufactured by NITTA DuPont Incorporated)
Rotation speed of platen (surface plate): 45 rpm
Rotation speed of head (carrier): 45 rpm
Polishing pressure (polishing load): 4.5 psi (316 g/cm²)
Flow rate of polishing composition: 100 ml/min
Polishing time: 1 min

### (Evaluation Method of Polishing Removal Rate)

1. Masses of an object to be polished before and after polishing were measured with an analytical balance XS205 (manufactured by Mettler-Toledo International Inc.). From a difference between the masses, a mass change ΔM (kg) of the object to be polished before and after polishing was calculated.
2. The mass change ΔM (kg) of the object to be polished before and after polishing was divided by a density of the object to be polished (density of material to be polished), to calculate a volume change ΔV (m3) of the object to be polished before and after polishing.
3. The volume change ΔV (m3) of the object to be polished before and after polishing was divided by an area S (m2) of a surface to be polished of the object to be polished, to calculate a thickness change Δd (m) of the object to be polished before and after polishing.
4. The thickness change Δd (m) of the object to be polished before and after polishing was divided by a polishing time t (min), and the unit was converted to (μm/min). The value was defined as polishing removal rate v [μm/min]. Although a higher polishing removal rate is preferred, a polishing removal rate of 4.0 μm/min or more is acceptable, and a polishing removal rate of 5.0 μm/min is desirable.

### [Residual Abrasive Grains on Surface]

The copper wire surface as an object to be polished after polishing used for evaluation on the polishing removal rate was photographed by a scanning electron microscope (SEM) (product name: SU8000, manufactured by Hitachi High-Tech Corporation), and the resulting SEM image was analyzed using an image analysis software (“WinROOF 2018” manufactured by Mitani Corporation). In more detail, the number of the abrasive grains (silica particles or alumina particles) present in an area of 110 μm by 110 μm in the SEM image was counted and converted into the number of residual abrasive grains per mm² (pieces/mm²), which was defined as the number of residual abrasive grains on the surface of the object to be polished after polishing. In the evaluation of the residual abrasive grains on the surface of the object to be polished, particles having a size of 200 nm or more and 10 μm or less were counted as residual abrasive grains. Accordingly, the residual abrasive grains are foreign matters having the size, which are present on the surface, and may include residues other than abrasive grains.

Although a lower number of residual abrasive grains on the surface of the object to be polished after polishing (pieces/mm²) is preferred, 1000×10³ pieces/mm² or less is acceptable, less than 600×10³ pieces/mm² is desirable, and less than 100×10³ pieces/mm² (“<100” in Table 1 and Table 2) is particularly desirable. In the following Table 1 and Table 2, the number of residual abrasive grains (pieces/mm²) on the surface of an object to be polished after polishing is described as “Number of residual abrasive grains on surface (10³ pieces/mm²)”.

TABLE 1

| | | Average | | | | | | |
|---|---|---|---|---|---|---|---|---|
| | | particle | Particle | | | | | |
| | | size of | size of | | | | | |
| | | abrasive | Abrasive | | Anticaking agent | | | |
| | Type of | grains | grains | | | Average | | |
| | abrasive | D₅₀ | D₁₀ | | | particle | | Specific |
| | grain | [μm] | [μm] | Circularity | Type | size | | gravity |
| Example 1 | silica | 6.4 | 2.8 | 0.97 | colloidal | 30 | nm | 3.9 |
| | | | | | alumina | | | |
| Example 2 | silica | 10.5 | 3.4 | 0.97 | colloidal | 30 | nm | 3.9 |
| | | | | | alumina | | | |
| Example 3 | silica | 6.4 | 2.8 | 0.97 | colloidal | 30 | nm | 3.9 |
| | | | | | alumina | | | |
| Example 4 | silica | 6.4 | 2.8 | 0.97 | colloidal | 30 | nm | 3.9 |
| | | | | | alumina | | | |
| Comparative | silica | 6.4 | 2.8 | 0.97 | colloidal | 30 | nm | 3.9 |
| Example 1 | | | | | alumina | | | |
| Comparative | silica | 6.4 | 2.8 | 0.97 | sodium | — | | — |
| Example 2 | | | | | polyacrylate | | | |
| Comparative | silica | 6.4 | 2.8 | 0.97 | crystalline | 200 | nm | 1.5 |
| Example 3 | | | | | cellulose | | | |
| Comparative | silica | 6.4 | 2.8 | 0.97 | crystalline | 200 | nm | 1.5 |
| Example 4 | | | | | cellulose | | | |
| Comparative | alumina | 6.9 | 4.7 | 0.63 | colloidal | 30 | nm | 3.9 |
| Example 5 | | | | | alumina | | | |

| | | | | | | | |
|---|---|---|---|---|---|---|---|
| Comparative | silica | 6.4 | 2.8 | 0.97 | — | — | — |
| Example 6 | | | | | | | |
| Comparative | silica | 6.4 | 2.8 | 0.97 | — | — | — |
| Example 7 | | | | | | | |
| Comparative | silica | 6.4 | 2.8 | 0.97 | — | — | — |
| Example 8 | | | | | | | |

| | | | | | | | Residual |
|---|---|---|---|---|---|---|---|
| | | | | | | | abrasive |
| | | | | | Polishing | | grain |
| | | Zeta potential [mV] | | | removal | Redis- | on Cu |
| | | Abrasive | Anticaking | | rate | persion | [10³ |
| | pH | grain | agent | Product | [μm/min] | property | pieces/mm²] |
| Example 1 | 9 | −54.0 | −8.9 | 481 | 5.8 | good | <100 |
| Example 2 | 9 | −54.0 | −8.9 | 481 | 8.4 | good | 190 |
| Example 3 | 8 | −53.4 | −5.0 | 267 | 6.1 | good | <100 |
| Example 4 | 2 | 0.8 | 7 | 6 | 6.1 | good | <100 |
| Comparative | 4 | −28.7 | 18.6 | −533 | 6.1 | poor | 586 |
| Example 1 | | | | | | | |
| Comparative | 9 | −54.0 | — | — | 6.1 | poor | 416 |
| Example 2 | | | | | | | |
| Comparative | 9 | −54.0 | −50 | 2700 | 6.1 | poor | 824 |
| Example 3 | | | | | | | |
| Comparative | 2 | 0.8 | 1.2 | 1 | 5.7 | poor | 494 |
| Example 4 | | | | | | | |
| Comparative | 9 | −21.4 | −8.9 | 190 | 6.5 | good | 1050 |
| Example 5 | | | | | | | |
| Comparative | 9 | −54.0 | — | — | 5.8 | poor | 642 |
| Example 6 | | | | | | | |
| Comparative | 4 | −28.7 | — | — | 6.1 | poor | 558 |
| Example 7 | | | | | | | |
| Comparative | 2 | 0.8 | — | — | 6.1 | poor | 792 |
| Example 8 | | | | | | | |

TABLE 2

| | | Particle | | | | | | | | | | Residual |
|---|---|---|---|---|---|---|---|---|---|---|---|---|
| | | size of | | | | | | | | | | abrasive |
| | | abrasive | | Anticaking | | | | | Substrate | Polishing | | grain |
| | Type of | grains | | agent | | Zeta potential [mV] | | | Filler | removal | Redis- | on Cu |
| | abrasive | D₅₀ | | (specific | | Abrasive | Anticaking | | size | rate | persion | [10³ |
| Example | grain | [μm] | Circularity | gravity) | pH | grain | agent | Product | [μm] | [μm/min] | property | pieces/mm²] |
| 5 | silica | 2.6 | 0.96 | colloidal | 9 | −54.0 | −8.9 | 481 | 1.0 | 14.0 | good | <100 |
| 6 | | | | alumina | | | | | 2.0 | 4.9 | | |
| 7 | | | | (specific | | | | | 3.0 | 0.9 | | |
| | | | | gravity: 3.9) | | | | | | | | |

As shown in Table 1, use of the polishing composition according to the present embodiment allows to have good redispersion properties, and allows an object to be polished to be polished at a high polishing removal rate, with a reduced number of residual abrasive grains on the surface of the object to be polished. On the other hand, when using the polishing compositions in Comparative Example 1 where the product of the zeta potential of the abrasive grains and the zeta potential of the anticaking agent was negative, in Comparative Examples 2 to 4 where the anticaking agent included water-soluble polymer or organic particles, and in Comparative Examples 6 to 8 where no anticaking agent was contained, the results were inferior to those of Examples in terms of the redispersion properties and the number of residual abrasive grains. Further, when using the polishing composition in Comparative Example 5 where aluminum particles were used as abrasive grains, the results were significantly inferior in terms of the number of residual abrasive grains, though the redispersion properties were good.

Further, in Examples 5 to 7, the size of filler contained in the object to be polished was changed with use of the same polishing composition, the polishing removal rate was improved with decrease in the filler size. It is presumed that there exists a relation to the particle size of the abrasive grains, and the reason is presumed that in the case where the filler size is smaller than the particle size of the abrasive grains, polishing can be efficiently achieved. On the other hand, in Examples 5 to 7, it is shown that all of the object to be polished had good redispersion properties, and the number of residual abrasive grains on the object to be polished could be reduced.

From these results, it is shown that the polishing composition of the present invention exhibits excellent effects including maintaining fluidity with good redispersion properties, allowing an object to be polished to be polished at a high polishing removal rate, and the number of residual abrasive grains on the surface of the object to be polished to be reduced.

The present application is based on Japanese Patent Application No. 2023-055871 filed on Mar. 30, 2023, and a disclosed content thereof is incorporated herein as a whole by reference.

1. A polishing composition comprising abrasive grains, an anticaking agent, and a dispersing medium, wherein
the abrasive grains are silica particles having an average particle size (D₅₀) of more than 1.0 μm and a circularity of primary particles of 0.90 or more,
the anticaking agent comprises inorganic particles different from the abrasive grains, and
a product of a zeta potential of the abrasive grains and a zeta potential of the anticaking agent is positive.

2. The polishing composition according to claim 1, wherein the anticaking agent comprises inorganic particles having an average particle size (D₅₀) of 500 nm or less.

3. The polishing composition according to claim 1, wherein the anticaking agent comprises alumina particles having an average particle size (D₅₀) of 200 nm or less.

4. The polishing composition according to claim 1, wherein the polishing composition is used for polishing an object to be polished containing a resin and a filler.

5. The polishing composition according to claim 4, wherein the silica particles have an average particle size (D₅₀) larger than an average particle size of the filler.

6. The polishing composition according to claim 5, wherein a ratio of the average particle size (D₅₀) of the silica particles to the average particle size of the filler is more than 1 and 15 or less.

7. A method for producing a polishing composition containing abrasive grains, a dispersing medium and an anticaking agent, the method comprising:
selecting silica particles having an average particle size (D₅₀) of more than 1.0 μm and a circularity of primary particles of 0.90 or more as the abrasive grains;
selecting inorganic particles different from the abrasive grains as the anticaking agent; and
mixing the silica particles and the anticaking agent with the dispersing medium.

8. A polishing method comprising polishing an object to be polished containing a resin and a filler by using the polishing composition according to claim 1.

9. The method according to claim 8, wherein the resin has a cyclic molecular structure.
